(19) United States
(12) Patent Application Publication
(10) Pub. No.: US 2009/0166181 A1
(43) Pub. Date: Jul. 2, 2009

(54) SPUTTER DEPOSITION OF METAL ALLOY TARGETS CONTAINING A HIGH VAPOR PRESSURE COMPONENT

(76) Inventors: Christopher J. Jezewski, Hillsboro, OR (US); Juan Dominguez, Hillsboro, OR (US)

Correspondence Address: INTEL CORPORATION;c/o CPA Global, P.O. BOX 52050, MINNEAPOLIS, MN, 55402, US

(21) Appl. No.: 11/968,131

(22) Filed: Dec. 31, 2007

(51) Int. Cl. C23C 14/34; C23C 14/56

(52) U.S. Cl. 204/192.1; 204/298.13

(57) ABSTRACT

Compositions and methods for enabling sputter deposition from targets containing high vapor pressure compounds are describe. An element or compound with a high vapor pressure may be combined with an element or compound with a lower vapor pressure to form a low vapor pressure compound. An alloy sputtering target may then be formed by combining the low vapor pressure compound with a metal that serves as the main material of the sputter target. In some instances, the low vapor pressure compound may comprise MgB₂, MgB₄, or MgB₇. Additionally, the metal that serves as the main material of the sputter target may comprise copper. As a result, the alloy target may comprise Cu(MgB₂), Cu(MgB₄), or Cu(MgB₇). Other embodiments are also described.

### FIELD

This application relates generally to compositions and methods for physical vapor deposition of thin films.

### BACKGROUND

Physical vapor deposition (“PVD”) condenses a vaporized form of a material (such as a metal, non-metal or alloy) onto a substrate (such as a semiconductor wafer) to deposit a thin film of that material on the substrate. One type of PVD, sputter deposition, deposits one or more thin films on a substrate by sputtering material from a target and allowing the material to deposit on the substrate.

Copper may be used as one material in a sputtering target. In order to increase the adhesion of copper to the substrate, as well as to improve interconnect reliability and reduce electromigration in the resulting Cu films, some sputtering targets may also contain additional materials. The addition of other materials to the copper target, however, dilutes the concentration of the copper in the sputtering target.

Tin, silicon, and aluminum are some materials that have often been used along with copper in sputtering targets. These materials have been used since they can diffuse to interfaces where it enhances thin film adhesion and reduce electromigration. But there exist other elements that have properties that may potentially improve interconnect reliability and reduce electromigration more and, therefore, could also be used as materials in sputtering targets. But many of those elements have vapor pressures that are too high to allow them to be used along with copper in sputtering targets. High vapor pressure can cause issues of re-deposition on chamber walls, particle formation, arcing and preferential sputtering. Accordingly, many of those elements have not been used in sputter deposition processes.

### BRIEF DESCRIPTION OF THE DRAWINGS

The following description can be better understood in light of the Figures, in which:

FIG. 1 contains a flow chart illustrating some embodiments of a method for sputter deposition using targets containing one or more high vapor pressure elements (or dopants);

FIG. 2 contains one example of a graph showing the differences in vapor pressures for some dopants that can be used in sputtering targets; and

FIGS. 3a and 3b contain phase diagrams, with FIG. 4a containing a phase diagram for an alloy of copper and boron, and FIG. 4b containing a phase diagram for an alloy of copper and magnesium; and

FIG. 4 contains an illustration of a cut-away view of some embodiments of a sputter deposition apparatus.

Together with the following description, the Figures demonstrate and explain the principles of the compositions and methods for physical vapor deposition of thin films. In the Figures, the thickness of layers and regions are exaggerated for clarity. It will be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the compositions and methods for physical vapor deposition of thin films can be implemented and used without employing these specific details. For example, while the description focuses on thin films used in semiconductor devices, it can be modified to be used in any electronic device where a thin film is needed.

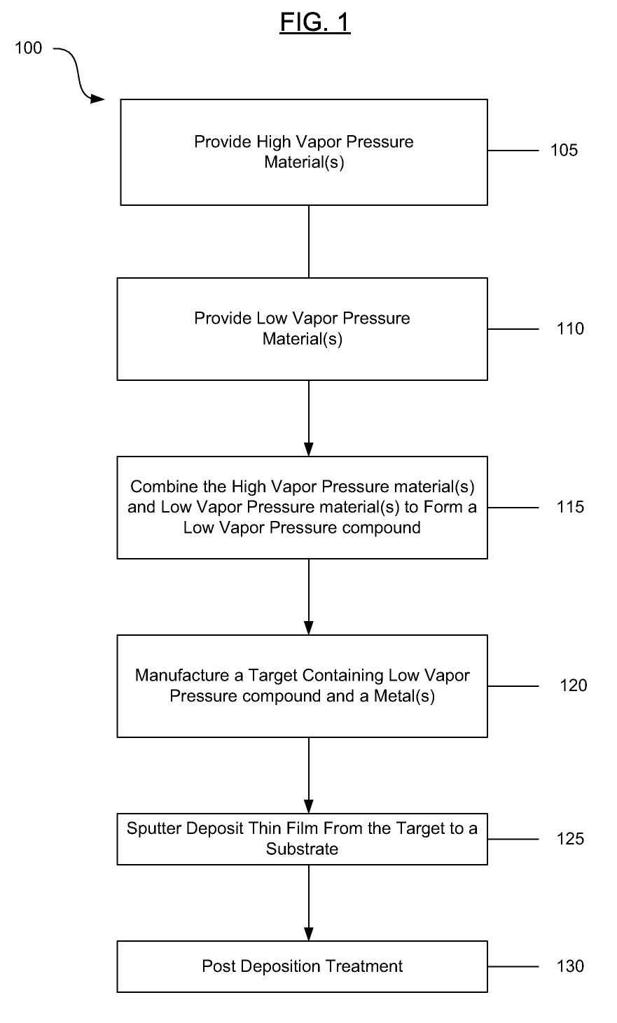

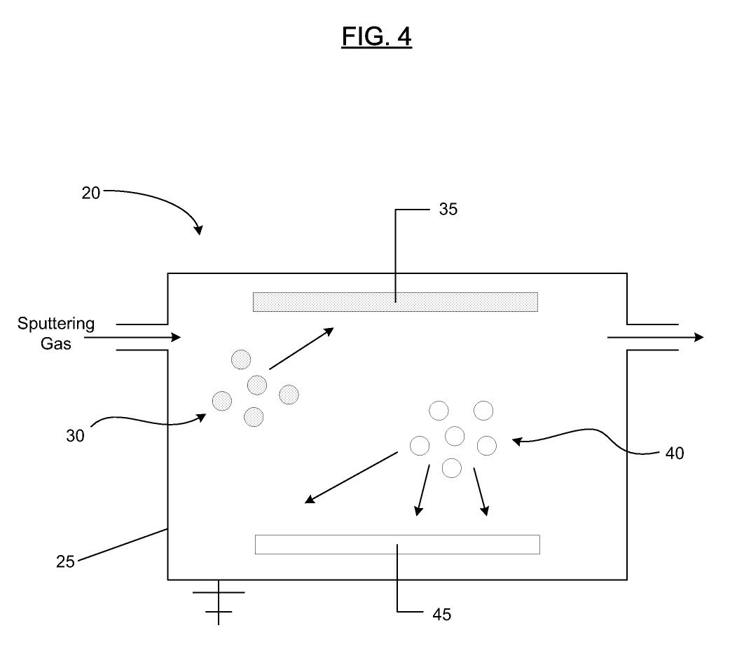

The sputter deposition uses a sputtering target (or target) that is made from a metal and a low vapor pressure compound. The low vapor pressure (VP) compound has been formed from a high vapor pressure material and a low vapor pressure material. The low vapor pressure compound has a lower vapor pressure than the high vapor pressure material used to make it. The sputtering target is made by alloying this low vapor pressure compound and a metal in a typical state of the art process. The sputtering target can then be used in any sputter deposition method, such as that method illustrated in FIG. 1, and any sputter deposition apparatus, such as that apparatus illustrated in FIG. 4.

As shown in block 105 of FIG. 1, the sputtering target is made by first providing one or more high vapor pressure materials, where that material may include one or more elements (whether alone or combined) with a high vapor pressure. The use of a high vapor pressure material(s) may increase the adhesion of the thin layer to the substrate as well as reduce electromigration. In some embodiments, a high vapor pressure material may refer to a material that has a vapor pressure over about 10⁻⁹ torr at about 1000 Celsius. Some non-limiting examples of suitable high vapor pressure materials may include calcium, cadmium, cesium, dysprosium, europium, gallium potassium, lithium, magnesium, manganese, rubidium, samarium, strontium, thallium, ytterbium, zinc, mixtures thereof, and combinations thereof. In some embodiments, magnesium may be used as the high vapor pressure material, as explained below.

Next, as shown in block 110, one or more low VP material(s) are provided, where that material may include one or more elements (whether alone or combined) with a low vapor pressure. The low VP material can have any vapor pressure that is lower than the vapor pressure of the high vapor pressure material. The lower pressure material may serve many purposes. In some embodiments, the lower pressure material is more stable and may serve to stabilize the high vapor pressure material. For example, the lower vapor pressure may stabilize the high vapor pressure material, thereby enabling sputtering in a manner that may cause little to no vacuum chamber coating or particle failure.

Some suitable low vapor pressure materials include any that lower the vapor pressure of the high vapor pressure material. Some non-limiting examples of low vapor pressure materials include any element (or compound) that forms an aluminate, boride, carbide, nitride, nitrate, or silicide and combinations thereof of the high vapor pressure material. Additionally, any lower vapor pressure material whose components have negligible or beneficial effects on the reliability of back end interconnects may be used as the low vapor pressure material. In some embodiments, a compound used to form borides of the high vapor pressure material may be used as the lower vapor pressure material.

A low vapor pressure compound is then made by combining the high vapor pressure material(s) and the low vapor pressure material(s), as shown in block 115. In some embodiments, a high vapor pressure material, such as magnesium, calcium, cadmium, cesium, dysprosium, europium, gallium, potassium, lithium, manganese, rubidium, samarium, strontium, thalium, ytterbium, or zinc, may be combined with one or more lower vapor pressure materials to form an aluminate, a boride, a carbide, a nitride, a nitrate, or a silicide of the high vapor pressure material. For example, magnesium may be combined with one or more elements to form a magnesium aluminate, a magnesium nitrate, a magnesium nitride, a magnesium boride (e.g., MgB₂, MgB₄, or MgB₇), a magnesium carbide, or a magnesium silicide. In another example, the low vapor pressure compound may comprise magnesium diboride or MgB₂. In yet another example, the low vapor pressure compound may comprise MgB₄ and MgB₇, which may be stable in sputter deposition process.

As shown in block 120 of FIG. 1, the low vapor pressure compound may then be combined with a metal(s) to make the sputter target. Examples of metals that can be used to make the target may include copper, aluminum, tungsten, titanium, hafnium, tantalum, iron, nickel, niobium, ruthenium, cobalt, palladium, platinum, silver, gold, and combinations and alloys thereof. In some embodiments, copper may be used as the metal of the target.

In some embodiments, the copper may be combined with the low vapor pressure compound to form a dilute copper alloy that is used in the target. For example, copper may be combined with magnesium diboride to form a dilute copper sputtering target that is alloyed with magnesium diboride, or a Cu(MgB₂) target. In this example, the incorporation of MgB₂ into the copper target may provide a source of Mg and B atoms to aid in electromigration resistance in a form that is compatible with conventional sputter deposition apparatus, as described in detail below.

The low vapor pressure compound (e.g., MgB₂) and the metal (e.g., copper) used in the target may be mixed at any suitable ratio. For example, a target may contain as little as 1 part copper, per billion parts MgB₂. In another example, a target may contain as much as 1 part MgB₂, per billion parts copper. Indeed in a typical embodiment a copper alloy target may comprise between about 1 part MgB₂ per million parts copper and about 1 part MgB₂ per ten parts copper.

The low vapor pressure compound may be added to the metal of the target in any known manner. For example, magnesium and boron may be added to a target comprising copper as the metal by adding MgB₂ to a copper melt and then molding, stamping, extruding, or otherwise manufacturing the target.

After the sputter target has been manufactured, that target can be used in sputter deposition process. As shown in block 125 of FIG. 1, the target may be used to sputter deposit a thin film on any desired substrate. This sputter deposition may be accomplished through any known or novel manner of sputter disposition. Some non-limiting examples of methods for sputter deposition may include ion-beam sputtering, reactive-ion sputtering, ion-assisted deposition, high-target-utilization sputtering, and/or high power impulse magnetron sputtering.

The thin film of material from the sputter target can serve many purposes. For example, the thin film may act as a seed layer for a plating superfill, as known in the art. Additionally, in another example, the deposited thin film may be used as the interconnect material or fill structure, as known in the art. In other examples, the film might be used both as barrier and seed for interconnects, where the volatile element creates a compound that can be used to prevent interconnect diffusion.

At block 130, FIG. 1 illustrates that after the thin film of target material has been formed on a substrate, the resulting structure may receive a post deposition treatment. Any known post deposition treatment of sputtered films can be performed. By way of example, the substrate and thin film may be treated with a conventional temperature or plasma anneal. Such treatments may be used to improve adhesion and/or to create a thin in-situ diffusion barrier. As well, the thin film may be coated or capped with an additional material, like pure copper, which may be used to protect and control the amount of compound incorporated into the seed stack.

The various processes in method 100 may be varied and can be carried out in any desired sequence. For example, the order may be varied, one or more process may be removed, and/or one or more process may be added. For example, the low vapor pressure compound need not be combined with the metal that to form a sputter target. Instead, the low vapor pressure compound itself may, where the needed elements are already present in that compound, be formed into a target. Then material from this target and from another target comprising a metal may be sputtered separately in a single process. For example, material from a target comprising MgB₂ may be sputtered on a substrate before, while, or after material from a target comprising copper is sputtered on the substrate.

Such a method can be performed using the sputter deposition apparatus depicted in FIG. 4. In this Figure, the sputter deposition apparatus 20 contains a vacuum chamber 25 where a glow plasma discharge, such as argon plasma 30, may bombard the material of the sputtering target 35. As the glow plasma discharge (e.g., argon plasma 30) bombards the sputtering target 35, the plasma may sputter some of the target 35 material away as a vapor. The sputtered atoms 40 from the target 35 that are ejected as a vapor may then be deposited on surfaces within the chamber 25, including towards a substrate 45. In this manner, the sputtered atoms 40 coat the exposed surfaces of the substrate 45 with a thin film of material from the target 35. The substrate 45 can be any known substrate in the art, including a semiconductor wafer, or a part of an integrated circuit.

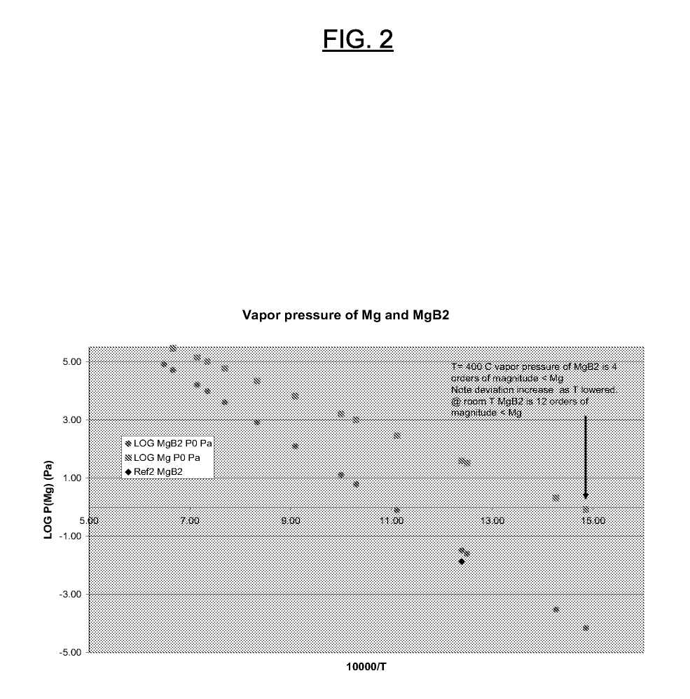

As an illustration of the compositions that can be used as a sputter target (and therefore a thin film on a substrate), FIG. 2 contains a graph showing the difference in vapor pressure between Mg and MgB₂. As previously mentioned, some elements that improve interconnect reliability, like magnesium, have such high vapor pressures that they have previously been considered impractical and/or unmanufacturable for use in sputter deposition targets. But when these elements are combined with other elements and/or compounds, the resulting compound may have a low vapor pressure that allows the previously unused element/compound to be used in sputter targets. Specifically, FIG. 2 illustrates that at 400 degrees Celsius, the vapor pressure of magnesium diboride may be about 4 orders of magnitude less than the vapor pressure of magnesium alone. As the temperature is lowered, the deviation between the vapor pressures of magnesium diboride and magnesium may deviate to the extent that the vapor pressure of magnesium diboride may be about 12 orders of magnitude less than that of magnesium at room temperature.

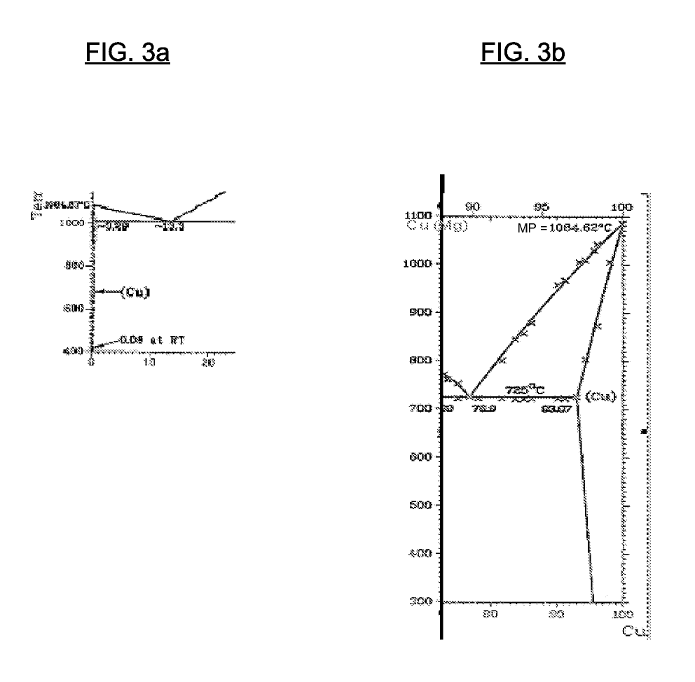

FIGS. 3a and 3b each contain a phase diagram illustrating how to combine (or alloy) copper and magnesium diboride to form Cu(MgB₂). FIG. 3a contains a phase diagram for an alloy of copper and boron. Similarly, FIG. 3b contains a phase diagram for an alloy of copper and magnesium. Although boron alone may be largely insoluble in copper, magnesium may be sufficiently soluble in copper to form an alloy. Magnesium, by itself at 1 atmosphere (“1 atm”) may melt at about 650 degrees Celsius and may begin to boil at about 1103 degrees Celsius. Moreover, at 1 atm, magnesium diboride may decompose at about 1268 degrees Celsius. FIG. 3b illustrates that, at 1 atm, copper may melt at about 1085 degrees Celsius. Accordingly, high purity magnesium diboride, and potentially MgB₄ and/or MgB₇, may be added to a copper melt that is between about 1085 degrees and about 1268 degrees Celsius.

Using sputter targets containing these compositions can be useful in sputter deposition process for several reasons. First, high vapor pressure elements that were previously unusable can now be used in sputter deposition process. Second, one or more high vapor pressure elements and/or compounds in conjunction with at least one lower pressure element and/or compound in a sputter target comprising a metal increases the interconnect reliability of the resulting film. Third, using the appropriate alloying and stabilizing elements may enhance adhesion to any etch stop and dopant surface diffusion layers underneath the thin film, as well as potentially forming a barrier to inter-diffusion with the interconnect metal. Fourth, using these compositions in thin films allows a wide range of interconnect scaling. Fifth, the high vapor pressure elements/compounds may offer additional resistance benefits that are not offered by silicon, tin, or aluminum. Sixth, the low vapor pressure compounds and/or alloys thereof can be used for electromigration reduction, formation of self formed barriers, and in overburden doping. As well, the low vapor pressure compounds and/or alloys thereof can be formed into bilayers with ruthenium because of the possible ruthenium compatibility with silicon, tin, and/or aluminum.

Having described the preferred aspects of the compositions and associated methods, it is understood that the appended claims are not to be limited by particular details set forth in the above description, as many apparent variations thereof are possible without departing from the spirit or scope thereof.

1. A sputter target used in sputter deposition, the target comprising:
a low vapor pressure compound containing:
a high vapor pressure material with a vapor pressure greater than about 1×10⁻⁹ Torr at about 1000 Celsius; and
a low vapor pressure material having a vapor pressure lower than the high vapor pressure material.

2. The sputter target of claim 1, wherein the high vapor pressure material comprises calcium, cadmium, cesium, dysprosium, europium, gallium, potassium, lithium, magnesium, manganese, rubidium, samarium, strontium, thallium, ytterbium, zinc, or combinations thereof.

3. The sputter target of claim 1, wherein the high vapor pressure material comprises magnesium.

4. The sputter target of claim 1, wherein the low vapor pressure compound comprises an aluminate, a boride, a carbide, a nitride, a nitrate, or a silicide and combinations thereof of the high vapor pressure material.

5. The sputter target of claim 4, wherein the low vapor pressure compound comprises MgB₂, MgB₄, or MgB₇.

6. The sputter target of claim 1, wherein the sputter target further comprises a metal combined with the low vapor pressure compound.

7. The sputter target of claim 6, wherein the metal in the sputter target comprises copper, aluminum, tungsten, titanium, hafnium, tantalum, iron, nickel, niobium, ruthenium, cobalt, palladium, platinum, silver, gold, or combinations thereof

8. The sputter target of claim 7, wherein the metal in the sputter target comprises copper.

9. A method for sputter deposition of a thin film, comprising:
providing a high vapor pressure material;
providing a low vapor pressure material having a vapor pressure lower than the high vapor pressure material;
mixing the high vapor pressure material and the low vapor pressure material to form a low vapor pressure compound; and
forming a sputter target using the low vapor pressure compound.

10. The method of claim 9, wherein the high vapor pressure material comprises calcium, cadmium, cesium, dysprosium, europium, gallium, potassium, lithium, magnesium, manganese, rubidium, samarium, strontium, thallium, ytterbium, zinc, or combinations thereof.

11. The method of claim 9, wherein the low vapor pressure compound comprises an aluminate, a boride, a carbide, a nitride, a nitrate, or a silicide or combinations thereof of the high vapor pressure material.

12. The method of claim 9, further comprising forming the sputter target by combining the low vapor pressure compound with a metal.

13. The method of claim 12, wherein the metal comprises copper, aluminum, tungsten, titanium, hafnium, tantalum, iron, nickel, niobium, ruthenium, cobalt, palladium, platinum, silver, or gold.

14. The method of claim 9, wherein the sputter target comprises Cu(MgB₂), Cu(MgB₄), or Cu(MgB₇).

15. The method of claim 9, further comprising depositing a thin film on a substrate using the sputter target.
